(19) United States
(12) Patent Application Publication
(10) Pub. No.: US 2010/0014247 A1
(43) Pub. Date: Jan. 21, 2010

(54) ANTI-TURBULENT CASING

(75) Inventors: Feng-Ku Wang, Taoyuan County (TW); Yi-Lun Cheng, Taipei County (TW)

Correspondence Address: J C PATENTS, 4 VENTURE, SUITE 250, IRVINE, CA, 92618, US

(73) Assignee: Inventec Corporation, Taipei City (TW)

(21) Appl. No.: 12/503,290

(22) Filed: Jul. 15, 2009

(30) Foreign Application Priority Data
Jul. 16, 2008 (TW) 97126995

(51) Int. Cl. H05K 7/20

(52) U.S. Cl. 361/692; 361/690

(57) ABSTRACT

An anti-turbulent casing includes a plate and an airflow guiding element. The plate has a first surface and a second surface opposite to the first surface. The first surface faces outward, and the second surface faces an interior of an electronic device. In addition, the plate has an opening passing through the first surface and the second surface. The airflow guiding element is disposed on the plate and has a curved surface and two sidewall surfaces connected between the curved surface and the second surface, and the curved surface protrudes out of the second surface and extends on top of the opening. The airflow guiding element makes the cooling airflow in a state of laminar.

### CROSS-REFERENCE TO RELATED APPLICATION

This application claims the priority benefit of Taiwan application serial no. 97126995, filed on Jul. 16, 2008. The entirety of the above-mentioned patent application is hereby incorporated by reference herein and made a part of specification.

### BACKGROUND OF THE INVENTION

1. Field of the Invention

The present invention generally relates to a casing, in particular, to an anti-turbulent casing.

2. Description of Related Art

Recently, computer and information industries have been developed continuously and vigorously. No matter for a desktop computer, a portable computer, or a server, the heat-dissipating capability thereof must be improved as the heat density in a smaller volume is increased, so that the working temperatures of a central processing unit (CPU), a chipset, or other heating sources within the casing are maintained at a normal level.

The host of a portable computer includes a motherboard, a CPU, a memory, a hard disk drive, a recorder, and/or optical disk drive, and the like, and the above electronic elements are accommodated in a computer casing with minimum disposition spaces thereof, such that the size of the portable computer is reduced, which is convenient for the user to take along. However, such a dense disposition manner brings troubles to effectively dissipate the waste heats accumulated in the casing, and it cannot effectively guide the cooling airflow into the casing. Meanwhile, due to the limitation on the size, a heat sink or a fan with a large size cannot be disposed in the casing, and the heat dissipating capability of the host cannot be significantly enhanced.

In order to successfully guide the cooling airflow into the casing, and guide the redundant heats out of the casing in a convection manner, at least one inlet and a plurality of outlets are reserved on a side surface, a bottom surface of the casing, or a surface of the casing where the keyboard is disposed, such that the cooling airflow is guided therein via the inlet in a natural or forced manner, and then, after absorbing the waste heats, the airflow is guided out via the outlets. However, if the cooling airflow is not properly guided toward the heating sources through appropriate channels, the cooling airflow aimlessly flows within the casing, which cannot be used effectively. What's worse, the non-uniformity of the flow field may occur, and it is possible to result in a partial high temperature concentration phenomenon, which needs to be improved urgently.

In addition, if channels or other flow field modification mechanisms are added in the portable computer, the cooling airflow may stably pass over the heating source and take away the heats of the heat sink or heat pipe on top of the heating source, so as to solve the partial high temperature concentration problem. However, due to the added channels, the entire thickness of the portable computer is increased, or the disposition spaces among the electronic devices become much denser. Subsequently, due to the cost factors on assembling or maintenance process, it cannot effectively meet the market demands on both high heat dissipation and small size.

### SUMMARY OF THE INVENTION

Accordingly, the present invention is directed to an anti-turbulent casing, which is suitable for making a cooling airflow in a state of laminar, and enhancing an electrostatic discharge protection.

As embodied and broadly described herein, the present invention provides an anti-turbulent casing, which includes a plate and an airflow guiding element. The plate has a first surface and a second surface opposite to the first surface. The first surface faces outward, and the second surface faces an interior of an electronic device. In addition, the plate has an opening passing through the first surface and the second surface. The airflow guiding element is disposed on the plate and has a curved surface and two sidewall surfaces connected between the curved surface and the second surface, and the curved surface protrudes out of the second surface and extends on top of the opening.

The present invention further provides an anti-turbulent casing, which includes a plate, a first airflow guiding element, and a second airflow guiding element. The plate has a first surface and a second surface opposite to the first surface, the first surface faces outward, and the second surface faces an interior of the electronic device. In addition, the plate has a first opening and a second opening passing through the first surface and the second surface. The first airflow guiding element is disposed on the plate and has a first curved surface and two first sidewall surfaces connected between the first curved surface and the second surface, and the first curved surface protrudes out of the second surface and extends on top of the first opening. The second airflow guiding element is disposed on the plate and has a second curved surface and two second sidewall surfaces connected between the second curved surface and the second surface, and the second curved surface protrudes out of the second surface and extends on top of the second opening, in which the first curved surface and the second curved surface extend to different orientations.

In an embodiment of the present invention, the airflow guiding element is integrally formed on the plate.

In an embodiment of the present invention, the electronic device has a heating element therein, and the curved surface of the airflow guiding element faces the heating element.

In an embodiment of the present invention, a ground part is disposed on the second surface of the plate, and electrically connected to a conductive layer, so as to form a ground via.

In an embodiment of the present invention, the ground part includes a metal sheet or conductive foam.

In an embodiment of the present invention, the curved surface of the airflow guiding element has a first contracted sheet thereon, and the first contracted sheet faces the second surface.

In another embodiment of the present invention, the second surface of the plate has a second contracted sheet thereon, and the second contracted sheet faces the curved surface.

In the present invention, through adopting the anti-turbulent casing with the airflow guiding element, a cooling airflow enters into the electronic device via the opening, the cooling airflow stably flows along the second surface of the casing, and pass over the heating element, so as to take away the heats in the casing. Therefore, the anti-turbulent casing of the present invention can improve the heat-dissipation performance of the electronic device, and the curved surface and the two sidewall surfaces of the airflow guiding element can also enhance the electrostatic discharge protection.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a general schematic view of an interior of an electronic device applying a first embodiment of the present invention.

FIG. 2 is a schematic view of a second surface of an anti-turbulent casing according to the first embodiment of the present invention.

FIGS. 3A and 3B are partial cross-sectional views of an anti-turbulent casing according to another embodiment of the present invention.

FIG. 4 is a schematic view of a second surface of an anti-turbulent casing according to a second embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

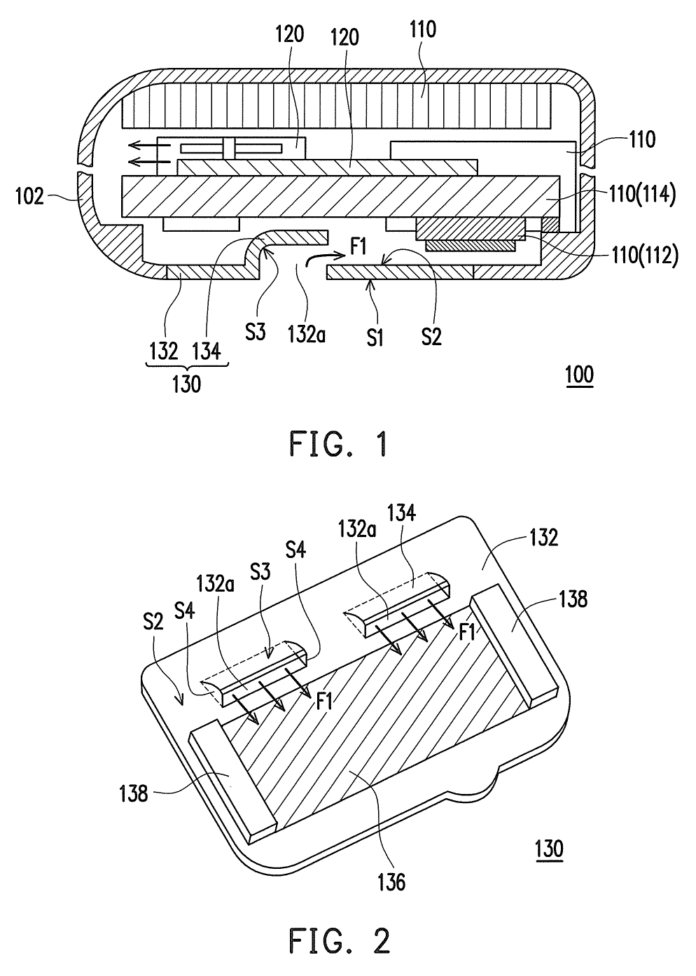

FIG. 1 is a general schematic view of an interior of an electronic device applying a first embodiment of the present invention, and FIG. 2 is a schematic view of a second surface of an anti-turbulent casing according to the first embodiment of the present invention. In this embodiment, an electronic device 100 adopting the present invention is, for example, a portable folding computer, a touchpad computer, a mobile communication computer, a communication device, a satellite navigation device, a nettop, or a multi-functional audio-visual media. FIG. 1 is a general schematic view showing disposition relations between electronic elements 110 and heat dissipating components 120 within the electronic device 100, and a working principle of the anti-turbulent casing 130 without limiting the scope protected by the present invention.

Referring to FIG. 1, the electronic device 100 includes a plurality of electronic elements 110 and a plurality of heat dissipating components 120 therein, in which the electronic elements 110 may be selected from a motherboard, a CPU, a chipset, a keyboard, a memory, a hard disk drive, a recorder, and/or an optical disk drive, and the like, so as to form the host of the electronic device 100. In addition, the heat dissipating components 120 may be selected from a heat sink fin, a heat pipe, a fan, and the like, so as to effectively transfer and guide the heat generated by the electronic elements 110, such that the working temperature in the casing 102 is maintained at a normal level.

In this embodiment, in order to successfully guide the cooling airflow into the casing 102 and guide the redundant heats out of the casing 102 in a convection manner, at least one inlet (not shown) and a plurality of outlets (not shown) are reserved on a side surface, a bottom surface, or a top surface of the casing 102, and an anti-turbulent mechanism is disposed on a plate 132 of the casing 102, so that the cooling airflow maintains a state of laminar after entering into the anti-turbulent casing 130.

Referring to FIGS. 1 and 2, the plate 132 has a first surface S1 and a second surface S2 opposite to the first surface S1. The first surface S1 faces outward, the second surface S2 faces the interior of the electronic device 100, and the plate 132 has an opening 132a passing through the first surface S1 and the second surface S2. In addition, the airflow guiding element 134 has a curved surface S3 and two sidewall surfaces S4 (only shown in FIG. 2) connected between the curved surface S3 and the second surface S2. The curved surface S3 protrudes out of the second surface S2 and extends on top of the opening 132a. The two openings 132a as shown in FIG. 2 are, for example, elongated slots. The curved surface S3 of the airflow guiding element 134 may protrude upwards from a long edge of the opening 132a and extend on top of the opening 132a, such that when a cooling airflow F1 from the exterior passes through the opening 132a, the curved surface S3 of the airflow guiding element 134 may guide the cooling airflow F1 to flow towards a gap between the airflow guiding element 132 and the second surface S2, so that the flow field of the cooling airflow F1 maintains in a state of laminar when the cooling airflow F1 passes through the second surface S2.

In this embodiment, the cooling airflow F1 in a state of laminar may move towards a preset path, so as to prevent the cooling airflow from changing the flowing direction in the midcourse to result in poor heat-dissipating effects. When the electronic device 100 has a heating element 112 therein, for example, the motherboard, CPU, chipset, and another electronic component, the curved surface S3 of the airflow guiding element 134 is made to face the heating element 112, such that the cooling airflow F1 stably passes over the heating element 112, and takes away the heats of the heat sink or the heat pipe on top of the heating element 112. Accordingly, the number of airflow guiding elements 134 and the orientation of the curved surface S3 may be appropriately adjusted depending upon the flow field design and the number and position of the heating elements 112 within the electronic device 100.

In this embodiment, the airflow guiding element 134 is, for example, integrally formed on the plate 132 by means of punching. Alternatively, the airflow guiding element 134 may be fabricated independently and then fixed on the plate 132 by means of soldering, riveting, or clamping. In addition, the plate 132, as a part of the casing 102, may be assembled on an appropriate position, for example, the side surface, bottom surface, and/or top surface of the casing 102, by means of locking or snapping. It should be noted that, in FIG. 1, when the plate 132 is disposed on the bottom surface of the casing 102, an appropriate safe distance is originally reserved between the motherboard 114 and the bottom surface by copper pillars, and thus, even if the airflow guiding element 134 bends inwards, it merely occupies a small part of the space in the electronic device 100.

Referring to another embodiment shown in FIG. 2, the airflow guiding element 134 is disposed on the plate 132 for forming a stable cooling airflow F1, and furthermore, a conductive layer 136 is disposed on the second surface S2 of the plate 132. When the plate 132 is a plastic product or made of a nonconductive material, the conductive layer 136 can protect the electronic device 100 from being damaged by electrostatic discharging, and the curved surface S3 on top of the opening 132a and the two sidewall surfaces S4 further enhance the electrostatic discharge protection. The conductive layer 136, for example, entirely or selectively covers an area of the second surface S2 adjacent to the opening 132a, and the conductive layer 136 may be made of aluminium foil or metal coating. In this embodiment, the size of the opening 132a is, for example, smaller than or equal to 2 cm, and the maximum distance between the airflow guiding element 134 and the second surface S2 may be smaller than or equal to 1 cm, so as to meet the requirements on the safety design of the electronic device. In addition, in order to protect the electronic components 110 from being damaged by the electrostatic discharging, the conductive layer 136 is further electrically connected to a ground plane of the electronic device 100 through at least one ground part 138, so as to form a ground via. The ground part 138 is disposed on the second surface S2 of the plate 132, which is, for example, a metal sheet (spring or elastomer) or conductive foam, so as to appropriately protect the electronic device 100.

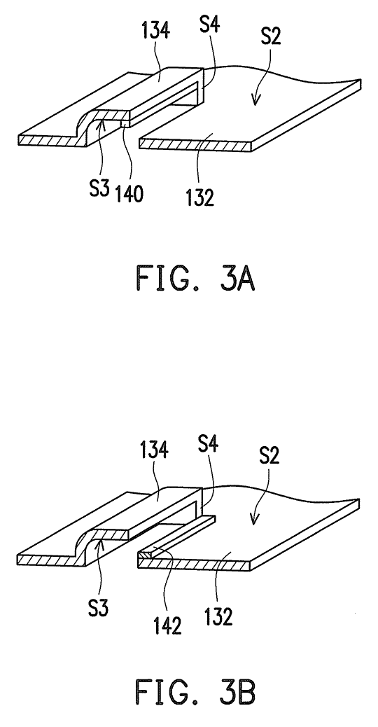

Next, referring to FIGS. 3A and 3B, they are partial cross-sectional views of an anti-turbulent casing according to another embodiment of the present invention. It is different from the above embodiment in that, besides the airflow guiding element disposed on the plate 132 for forming a stable cooling airflow, a first contracted sheet 140 and/or a second contracted sheet 142 is further disposed. Referring to FIG. 3A, a first contracted sheet 140 is configured on the curved surface S3 of the airflow guiding element 134, and the first contracted sheet 140 faces the second surface S2, so as to reduce the maximum gap between the airflow guiding element 134 and the second surface S2. In addition, in FIG. 3B, a second contracted sheet 142 is configured on the second surface S2 of the plate 132, and the second contracted sheet 142 faces the curved surface S3, so as to reduce the maximum gap between the airflow guiding element 134 and the second surface S2. Therefore, the maximum gap between the airflow guiding element 134 and the second surface S2 may be reduced, for example, reduced from 1 cm to 0.8 cm.

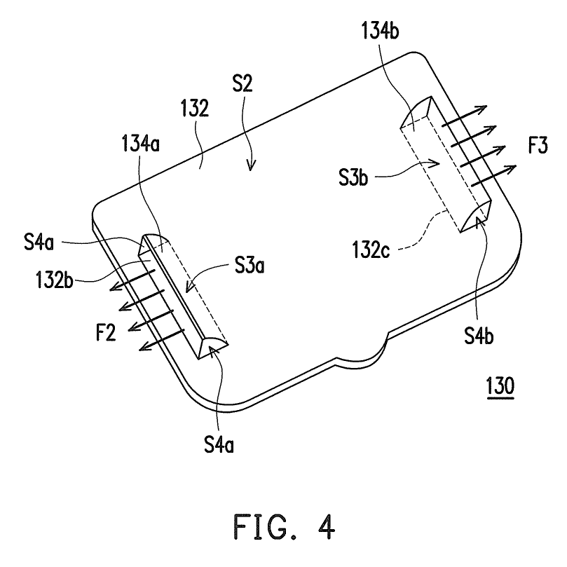

Furthermore, referring to FIG. 4, it is a schematic view of a second surface of an anti-turbulent casing according to a second embodiment of the present invention. The plate 132 has a first surface S1 and a second surface S2 opposite to the first surface S1. The first surface S1 faces outward, and the second surface S2 faces an interior of the electronic device 100, as described in the first embodiment. However, it is different from the first embodiment in that, the plate 132 has a first opening 132b and a second opening 132c passing through the first surface S1 and the second surface S2. In addition, the first airflow guiding element 134a has a first curved surface S3a and two first sidewall surfaces S4a connected between the first curved surface S3a and the second surface S2, and the first curved surface S3a protrudes out of the second surface S2 and extends on top of the first opening 132b. In addition, the second airflow guiding element 134b has a second curved surface S3b and two second sidewall surfaces S4b connected between the second curved surface S3b and the second surface S2, and the second curved surface S3b protrudes out of the second surface S2 and extends on top of the second opening 132c. It should be noted that, the first curved surface S3a and the second curved surface S3b respectively extend to different orientations, such that a cooling airflow from the exterior which is guided therein via the first curved surface S3a and the second curved surface S3b flow to different orientations, so as to respectively form a first airflow F2 and a second airflow F3 in a state of laminar. Therefore, when the electronic device 100 includes a plurality of heating elements 112 therein, the curved surfaces of the first and second airflow guiding elements are made to face different heating elements 112, such that cooling airflows stably pass over the heating elements 112 respectively, and take away the heats of the heat sink or heat pipe on top of the heating elements 112, without interfering each other.

Considering the further descriptions about the plate, the first airflow guiding element, and the second airflow guiding element, for example, the improving measures of disposing the plate on the second surface of the conductive layer to prevent the electronic device from being damaged by the electrostatic discharging, the material of the conductive layer, the size design of the opening, electrically connecting the ground part to the conductive layer to form the ground via, the material of the ground part, and configuring the first contracted sheet and/or the second contracted sheet to reduce the maximum gap between the airflow guiding element and the second surface, may be taken in the second embodiment respectively or simultaneously, and the detailed descriptions are not given here.

To sum up, in the present invention, through adopting the anti-turbulent casing with the airflow guiding element, when a cooling airflow enters into the electronic device via the opening, the cooling airflow stably flows along the second surface of the casing, and passes over the heating element, so as to take away the heats in the casing. Therefore, the anti-turbulent casing of the present invention can improve the heat-dissipation performance of the electronic device, and the curved surface and the two sidewall surfaces of the airflow guiding element can enhance the electrostatic discharge protection. In addition, the plate, as a part of the casing, does not occupy any element-disposition space of the electronic device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An anti-turbulent casing, applicable to an electronic device, comprising:
a plate, having a first surface and a second surface opposite to the first surface, wherein the first surface faces outward, the second surface faces an interior of the electronic device, and the plate has an opening passing through the first surface and the second surface; and
an airflow guiding element, disposed on the plate, and having a curved surface and two sidewall surfaces connected between the curved surface and the second surface, wherein the curved surface protrudes out of the second surface and extends on top of the opening.

2. The anti-turbulent casing according to claim 1, wherein the airflow guiding element is integrally formed on the plate.

3. The anti-turbulent casing according to claim 1, wherein the electronic device comprises a heating element therein, and the curved surface of the airflow guiding element faces the heating element.

4. The anti-turbulent casing according to claim 1, further comprising a conductive layer, disposed on an area of the second surface adjacent to the opening.

5. The anti-turbulent casing according to claim 4, further comprising a ground part, disposed on the second surface of the plate, and electrically connected to the conductive layer, so as to form a ground via.

6. The anti-turbulent casing according to claim 5, wherein the ground part comprises a metal sheet or conductive foam.

7. The anti-turbulent casing according to claim 1, wherein the curved surface of the airflow guiding element comprises a first contracted sheet thereon and the first contracted sheet faces the second surface.

8. The anti-turbulent casing according to claim 1, wherein the second surface of the plate comprises a second contracted sheet thereon and the second contracted sheet faces the curved surface.

9. An anti-turbulent casing, applicable to an electronic device, comprising:
a plate, having a first surface and a second surface opposite to the first surface, wherein the first surface faces outward, the second surface faces an interior of the electronic device, and the plate has a first opening and a second opening passing through the first surface and the second surface;
a first airflow guiding element, disposed on the plate, and having a first curved surface and two first sidewall surfaces connected between the first curved surface and the second surface, wherein the first curved surface protrudes out of the second surface and extends on top of the first opening; and
a second airflow guiding element, disposed on the plate, and having a second curved surface and two second sidewall surfaces connected between the second curved surface and the second surface, wherein the second curved surface protrudes out of the second surface and extends on top of the second opening, and wherein the orientation of the first curved surface extending to is different from that of the second curved surface extending to.

10. The anti-turbulent casing according to claim 9, wherein the first airflow guiding element and the second airflow guiding element are integrally formed on the plate.

11. The anti-turbulent casing according to claim 9, wherein the electronic device comprises a first heating element and a second heating element therein, the first curved surface of the first airflow guiding element faces the first heating element, and the second curved surface of the second airflow guiding element faces the second heating element.

12. The anti-turbulent casing according to claim 9, further comprising a conductive layer, disposed on an area of the second surface adjacent to the first opening and the second opening.

13. The anti-turbulent casing according to claim 12, further comprising a ground part, disposed on the second surface of the plate, and electrically connected to the conductive layer, so as to form a ground via.

14. The anti-turbulent casing according to claim 13, wherein the ground part comprises a metal sheet or conductive foam.
